(19) United States
(12) Patent Application Publication
(10) Pub. No.: US 2024/0341068 A1
(43) Pub. Date: Oct. 10, 2024

(54) CONVERTER

(71) Applicant: LG INNOTEK CO., LTD., Seoul (KR)

(72) Inventors: Ki Dong KIM, Seoul (KR); Byung Nam CHOI, Seoul (KR)

(73) Assignee: LG INNOTEK CO., LTD., Seoul (KR)

(21) Appl. No.: 18/716,335

(22) PCT Filed: Jan. 3, 2023
(86) PCT No.: PCT/KR2023/000109

§ 371 Date: Jun. 4, 2024

(30) Foreign Application Priority Data
Jan. 6, 2022 (KR) 10-2022-0002252

(51) Int. Cl. H05K 7/20; H02M 3/00

(52) U.S. Cl. CPC H05K 7/2089; H02M 3/003

(57) ABSTRACT

A converter comprises: a housing; and a heat dissipation passage disposed in the housing and having an inner flow channel through which a refrigerant flows, wherein an end of the heat dissipation passage has a shape protruding from the outer surface of the housing, an anti-rotation portion is disposed at the end of the heat dissipation passage, and a protrusion protruding outward beyond other areas is formed at the outer surface of the anti-rotation portion.

### TECHNICAL FIELD

The teachings in accordance with exemplary and non-limiting embodiments of this invention relate generally to a converter.

### BACKGROUND ARTS

The electrical system of a car includes the engine electrical system (starter, ignition, charging system) and lighting system, but in recent years, as vehicles have become more electronically controlled, most systems, including the chassis electrical system, are becoming electronically controlled.

The lamps, audio, heater, air conditioner, etc. installed in the car are powered by the battery when the car is stationary and by the generator when the car is driving, and the generating capacity of the 14V power system is used as the normal power supply voltage.

In recent years, with the development of the information technology industry, various new technologies (motorized power steering, internet, etc.) aimed at increasing the convenience of automobiles have been incorporated into vehicles, and the development of new technologies that can make the most of the current automobile system is expected to continue.

All hybrid electric vehicles (HEVs), whether soft or hard, are equipped with a low voltage DC-DC converter (DC-DC converter) to supply the electrical load (12 V). In addition, the DC-DC converter, which acts as a generator (alternator) in a conventional petrol vehicle, steps down the high voltage of the main battery (usually a high-voltage battery of 144 V or more) to supply 12 V for the electrical load.

A DC-DC converter is an electronic circuit device that converts DC power of one voltage to DC power of another voltage, and is used in a variety of applications, including automotive electronics and television receivers.

The converter is formed by a housing. Inside the housing, a number of electronic components are placed. The electronic components are driven and generate heat. The heat can overload the electronic components, which can interfere with their functioning and cause them to fail.

The converter includes a refrigerant flow path through which the refrigerant flows to dissipate heat from the components. The refrigerant flow path is disposed in a housing, and a refrigerant inlet portion and a refrigerant outlet portion are formed at each end thereof, and a refrigerant providing (delivery) portion for providing refrigerant and a refrigerant recovery portion for recovering the refrigerant flowing through the refrigerant flow path by discharging the refrigerant to the outside are combined at both ends of the refrigerant flow path.

Therefore, a structure for preventing arbitrary rotation is required in the connection of the refrigerant providing part, the refrigerant inlet part, the refrigerant recovery part, and the refrigerant outlet part, i.e., the different configurations.

### DETAILED DESCRIPTION OF THE INVENTION

### Technical Subject

It is an object of the present invention to provide a converter that allows a plurality of configurations to be securely coupled to each other by preventing arbitrary rotation of the configurations that are coupled to the refrigerant flow path (channel), and that allows for smooth inflow and outflow of refrigerant.

### Technical Solution

In one general aspect of the present invention, there may be provided a converter, comprising: a housing; and
a heat dissipation passage disposed in the housing and having an inner flow channel through which a refrigerant flows, wherein
an end of the heat dissipation passage has a shape protruding from the outer surface of the housing, an anti-rotation portion is disposed at the end of the heat dissipation passage, and a protrusion protruding outward beyond other areas is formed at the outer surface of the anti-rotation portion.

Preferably, but not necessarily, the protrusion may be plurally provided and arranged opposite each other.

Preferably, but not necessarily, the outer surface of the anti-rotation portion may be provided with a groove shaped to be recessed inwardly than in other areas.

Preferably, but not necessarily, the groove may be plural, and may be arranged on either side of the protrusions.

Preferably, but not necessarily, the anti-rotation portion may be formed with a smaller cross-sectional area than other regions of the heat dissipation passage.

Preferably, but not necessarily, the anti-rotation portion may include a connecting tube coupled to the anti-rotation portion.

Preferably, but not necessarily, the connecting tube may include a guide protruding outwardly from the other region, and the anti-rotation portion may be disposed on an inner side of the guide.

Preferably, but not necessarily, the anti-rotation portion and the heat dissipation passage may be integrally formed.

Preferably, but not necessarily, the sum of the circumferential lengths of each of the plurality of grooves may be greater than the circumferential length of the protrusion.

Preferably, but not necessarily, the heat dissipation passage may be integrally formed with the housing.

### Advantageous Effects

The exemplary embodiment of the present invention has the advantage that an anti-rotation structure is formed integrally at the end of the heat dissipation passage, eliminating the need for a separate component for anti-rotation, thereby improving production efficiency.

Furthermore, it has the advantage of being compatible with external configurations of various sizes by forming an appropriate tolerance through a plurality of grooves at both ends of the protrusion.

### BRIEF DESCRIPTION OF DRAWINGS

FIG. 1 is a perspective view illustrating the appearance of a converter according to an exemplary embodiment of the present invention.

FIG. 2 is an exploded perspective view of a converter according to an exemplary embodiment of the present invention.

FIG. 3 is a drawing showing FIG. 2 from a different angle.

FIG. 4 is a perspective view showing an upper surface of a housing according to an exemplary embodiment of the present invention.

FIG. 5 is a perspective view showing the lower surface of a housing according to an exemplary embodiment of the present invention.

FIG. 6 is an enlarged view of a refrigerant inlet or outlet region formed in the side of a housing according to an exemplary embodiment of the present invention.

FIG. 7 is an exploded perspective view to illustrate the coupling between the connecting tube and the refrigerant delivery portion, and the connecting tube and the refrigerant recovery portion, according to an exemplary embodiment of the present invention.

### BEST MODE

Hereinafter, exemplary embodiments of the present invention will be described in detail with reference to the accompanying drawings.

However, it should be noted that the technical ideas of the present invention should not be construed as limited to some of the explained exemplary embodiments but may be embodied in mutually different various shapes, and one or more elements may be selectively coupled or substituted among exemplary embodiments as long as within the scope of technical concept of the present invention.

Furthermore, terms (including technical and scientific terms) used in the embodiments of the present invention, unless expressly specifically defined and described, are to be interpreted in the sense in which they would be understood by a person of ordinary skill in the art to which the present invention belongs, and commonly used terms, such as dictionary-defined terms, are to be interpreted in light of their contextual meaning in the relevant art.

Furthermore, the terms used in the embodiments of the invention are intended to describe the embodiments and are not intended to limit the invent ion.

In this specification, the singular may include the plural unless the context otherwise requires, and references to “at least one (or more) of A and (or) B and C” may include one or more of any combination of A, B, and C that may be assembled.

In addition, the terms first, second, A, B, (a), (b), and the like may be used to describe components of embodiments of the invention. Such terms are intended only to distinguish one component from another, and are not intended to limit the nature or sequence or order of such components by such terms.

Furthermore, when a component is described as “connected,” “coupled,” or “attached” to another component, it can include cases where the component is “connected,” “coupled,” or “attached” to the other component directly, as well as cases where the component is “connected,” “coupled,” or “attached” to another component that is between the component and the other component.

Furthermore, when described as being formed or disposed “above” or “below” each component, “above” or “below” includes not only when two components are in direct contact with each other, but also when one or more other components are formed or disposed between the two components. Furthermore, when expressed as “above” or “below”, it may include the meaning of upward as well as downward with respect to a single component.

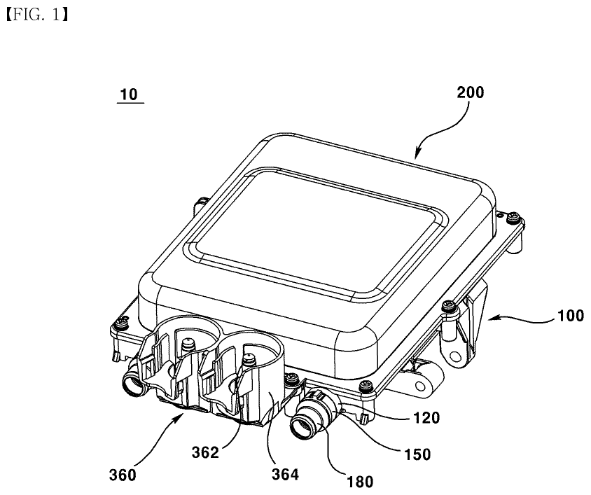

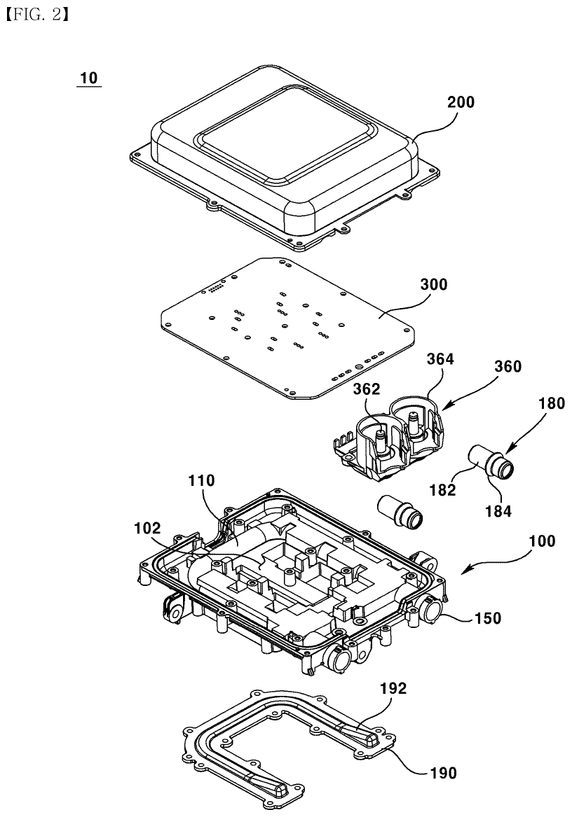

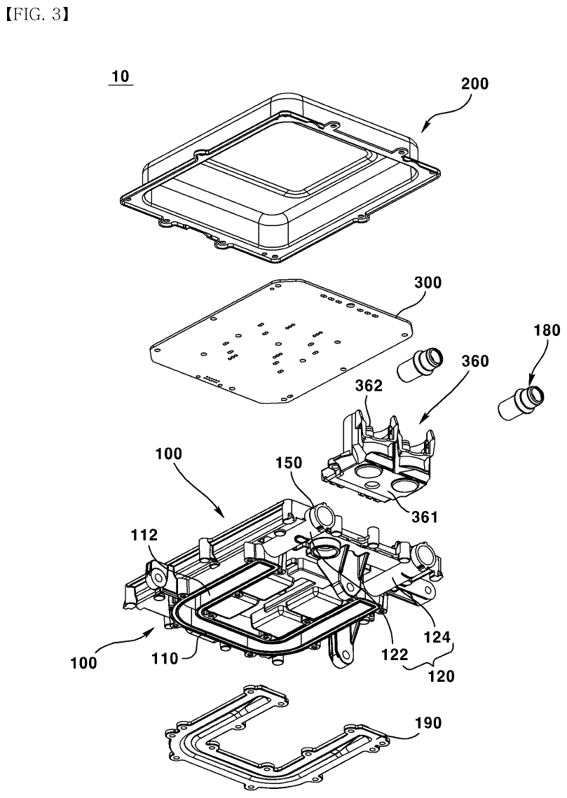

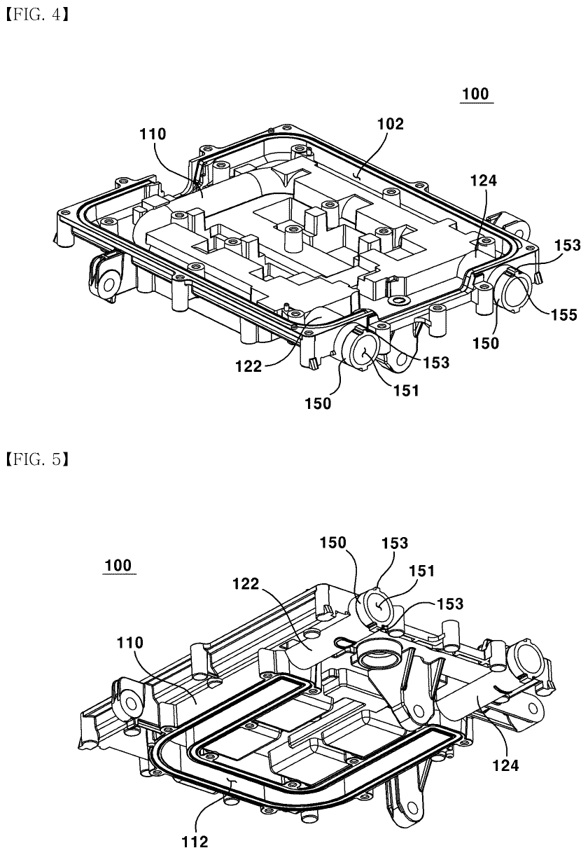

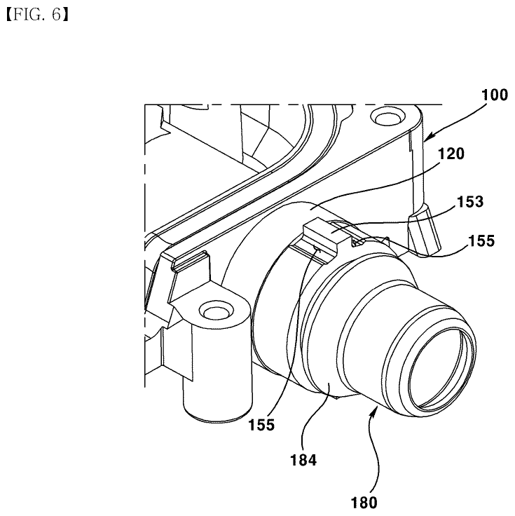

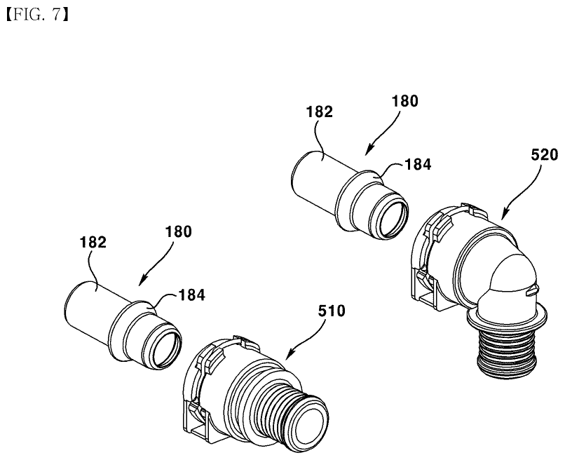

FIG. 1 is a perspective view illustrating the appearance of a converter according to an exemplary embodiment of the present invention, FIG. 2 is an exploded perspective view of a converter according to an exemplary embodiment of the present invention, FIG. 3 is a drawing showing FIG. 2 from a different angle, FIG. 4 is a perspective view showing an upper surface of a housing according to an exemplary embodiment of the present invention, FIG. 5 is a perspective view showing the lower surface of a housing according to an exemplary embodiment of the present invention, FIG. 6 is an enlarged view of a refrigerant inlet or outlet region formed in the side of a housing according to an exemplary embodiment of the present invention, and FIG. 7 is an exploded perspective view to illustrate the coupling between the connecting tube and the refrigerant delivery portion, and the connecting tube and the refrigerant recovery portion, according to an exemplary embodiment of the present invention.

Referring to FIGS. 1 to 7, a converter (10) according to an embodiment of the present invention may be shaped by a housing (100). The housing (100) may be formed of a metallic material. Within the housing (100), a space (102) may be formed in which at least one component for driving the converter (10) is arranged. The space (102) may be arranged on an upper surface of the housing (100).

On a lower surface of the housing (100), a refrigerant flow path (112) may be formed. The refrigerant flow path (112) may comprise a space in which a refrigerant flows therein. The refrigerant flow path (112) may have a refrigerant flow route defined from one end to the other, and may comprise a plurality of regions having different cross-sectional areas. The refrigerant flow path (112) may be at least partially open to a downward side of the housing (100).

The housing (100) may comprise a heat dissipation passage in which the refrigerant flow path (112) is formed. The heat dissipation passage may comprise a first heat dissipation passage (110) and a second heat dissipation passage (120).

To be more specific, on a lower surface of the housing (100), the first heat dissipation passage (110) and the second heat dissipation passage (120) protruding from both ends of the first heat dissipation passage (110) may be disposed. The refrigerant flow path (112) may be arranged in a space in the first heat dissipation passage (110) and in a space in the second heat dissipation passage (120), respectively.

The first heat dissipation passage (110) may have a square pipe shape and may be open at the lower side of the housing (100). The first heat dissipation passage (110) may have at least one bent region. The first heat dissipation passage (110) may be formed in a cross-section approximately in the shape of a “ [symbol] ”.

On the lower surface of the housing (100), a heat dissipation cover (190) may be disposed for covering the flow path (112) in the first heat dissipation passage (110). A sealing member (not shown) may be disposed between the heat dissipation cover (190) and the first heat dissipation passage (110). The cross-sectional shape of the heat dissipation cover (190) may correspond to the cross-sectional shape of the first heat dissipation passage (110).

The second heat dissipation passage (120) may protrude from both ends of the first heat dissipation passage (110) and may have a region where at least a portion of it protrudes outwardly from a side of the housing (100). The second heat dissipation passage (120) may have the shape of a pipe with a circular cross-section and may have the flow path (112) formed on its inner side. The cross-sectional area of the second heat dissipation passage (120) may be formed smaller than the cross-sectional area of the first heat dissipation passage (110). The cross-sectional area of the flow path (112) formed in the first heat dissipation passage (110) may be larger than the cross-sectional area of the flow path (112) formed in the second heat dissipation passage (120).

The second heat dissipation passage (120) may include a second-1 heat dissipation passage (122) disposed at one end of the first heat dissipation passage (110), and a second-2 heat dissipation passage (124) disposed at the other end of the first heat dissipation passage (110). Thus, refrigerant introduced into the flow path (112) via the second-1 heat dissipation passage (122) may circulate through the first heat dissipation passage (110) and be discharged to the outside via the second-2 heat dissipation passage (124). The second-1 heat dissipation passage (122) may be referred to as the refrigerant inlet passage and the second-2 heat dissipation passage (124) may be referred to as the refrigerant outlet passage.

The first heat dissipation passage (110) and the second heat dissipation passage (120) may have areas that at least partially overlap with components disposed in the space within the housing (100).

The first heat dissipation passage (110) and the second heat dissipation passage (120) may be integrally formed with the housing (100).

A cover (200) may be coupled to an upper surface of the housing (100). The cover (200) may be arranged to cover the space (102). The cover (200) may be screwedly coupled to the housing (100). Between the cover (200) and the housing (100), a sealing member (not shown) may be disposed to prevent external foreign objects from entering the space (102).

At least one electronic component may be disposed in the space (102). In one example, a printed circuit board (300) may be disposed in the space (102). The printed circuit board (300) may be formed in the shape of a plate, with at least one component disposed on an upper surface or a lower surface. The printed circuit board (300) may be arranged so as to at least partially overlap the first heat dissipation passage (110) or the second heat dissipation passage (120) in an upward or downward direction. The electronic components may be driven to generate heat.

A connector (360) may be disposed on the outer surface of the housing (100). The connector (360) may be at least partially coupled to the upper surface of the housing (100). The connector (360) may include a bracket (361), a plurality of pins (362) disposed to project upwardly from an upper surface of the bracket (361), and a compartment (364) compartmentalizing a space between the plurality of pins (362).

The plurality of pins (362) may have one end projecting upwardly from an upper surface of the bracket (361) and the other end extending through a space within the bracket (361) and into the housing (100) for connection with the printed circuit board (300). External terminals may be coupled to the plurality of pins (362), whereby a high voltage power source may be provided to the converter (10), a low voltage power source converted within the converter (10) may be provided to the external terminals, or a grounding structure of the ground region between configurations within the converter (10) and other configurations may be implemented.

In addition, the converter (10) may further include signal terminals for transmitting and receiving electrical signals between the converter (10) and other configurations.

As mentioned above, at least a portion of the second heat dissipation passage (120) may be disposed on an outer surface of the housing (100). On the outer surface of the housing (100), a distal end of the second heat dissipation passage (120) may be disposed. A hole (not shown) may be formed in the side of the housing (100) penetrating the outer surface from the inner surface, and the second heat dissipation passage (120) may be arranged to penetrate the hole.

In summary, it can be understood that a heat dissipation passage is arranged on the side of the housing (100), which protrudes outwardly from other areas, with the path (112) formed on the inner side.

At both ends of the heat dissipation passages projecting outwardly of the housing (100), anti-rotation portions (150) may be formed. The anti-rotation portions (150) may be formed with a cross-sectional area smaller than the cross-sectional area of the heat dissipation passage, i.e. the second heat dissipation passage (120). The anti-rotation portion (150) may have a circular cross-sectional shape. The anti-rotation portion (150) may be integrally formed with the heat dissipation passage.

The anti-rotation portion (150) may include a protrusion (153). The protrusion (153) may be shaped to protrude outwardly from an outer peripheral surface of the anti-rotation portion (150) more than other areas. A radial length from a center of the flow path (112) to an outer surface of the anti-rotation portion (150) may be formed smaller than a radial length from a center of the flow path (112) to an outer surface of the protrusion (153).

The protrusion (153) may have a square cross-sectional shape. The length of the protrusion (153) may correspond to the length of the anti-rotation portion (150) with respect to the direction of flow of the refrigerant. The protrusion (153) may be provided in plurality and arranged opposite each other. For example, when viewed from the side of the housing (100), the plurality of protrusions (153) may be disposed with one at 12 o'clock direction and another at 6 o'clock direction. The anti-rotation portion (150) may include a groove (155). The groove (155) may be formed to be recessed inwardly from an outer surface of the anti-rotation portion (150). The floor surface of the groove (155) may be disposed radially stepwise from the outer surface of the anti-rotation portion (150). The groove (155) may be plural in number and may be disposed on either side of a single protrusion (153). The plurality of grooves (155) may be disposed opposite each other relative to the protrusion (153). The sum of the circumferential lengths of each of the plurality of grooves (155) may be formed to be greater than the circumferential length of the protrusion (153).

Both ends of the heat dissipation passages may be coupled with a connecting tube (180, spigot). The connecting tube (180) may be formed in the shape of a pipe. The connecting tube (180) may be made of the same material as the housing (100), but may alternatively be made of a different material than the housing (100).

The connecting tube (180) may include a circular body (182) and a guide (184) formed on an outer surface of the body (182). The body (182) may be coupled at one end with the heat dissipation passage and coupled at the other end with a refrigerant providing (delivery) portion (510, see FIG. 7) or a refrigerant recovery portion (520), as will be described later. The body (182) may have a pipe shape such that a space for the refrigerant to flow is formed therein.

The guide (184) may be disposed between one end and the other end of the body (182), and may have a shape that protrudes outwardly from the other region. The guide (184) may have a ring-shaped cross-section and may be formed with a cross-sectional area larger than the cross-sectional area of the body (182). The anti-rotation portion (150) may be disposed on an inner side of the guide (184).

The connecting tube (180) may be coupled with a refrigerant providing portion (510) or a refrigerant recovery portion (520). The refrigerant providing portion (510) may be coupled to the connecting tube (180), which is disposed at one end of the heat dissipation passage, and may provide refrigerant to the flow path (112) in the heat dissipation passage. The refrigerant recovery portion (520) may be coupled to the connecting tube (180) disposed at the other end of the heat dissipation passage and may recover refrigerant discharged from the flow path (112) in the heat dissipation passage.

The refrigerant providing portion (510) and the refrigerant recovery portion (520) may each include a hole for receiving the anti-rotation portion (150), and an inner surface of the hole may be formed with a groove in which the protrusion (153) is engaged or coupled. Accordingly, by engagement (coupling) of the protrusions (153) and the grooves, the refrigerant providing portion (510) and the refrigerant recovery portion (520) may be prevented from arbitrary rotation while in engagement with the heat dissipation passage.

Furthermore, by forming a tolerance with the protrusion (153) in a circumferential direction through the groove (155) formed on the outer surface of the anti-rotation portion (150), it has the advantage of being compatible with external configurations of various sizes. In other words, since the floor surface of the groove (155) is formed in a radially stepped manner with the outer surface of the anti-rotation portion (150), it is advantageous to be able to respond to the occurrence of a tolerance in the width direction of the protrusion (153).

Although all of the components comprising an embodiment of the present invention have been described above as being combined or operating in combination, the invention is not necessarily limited to such embodiments, i.e., all of the components may optionally be combined in one or more combinations, provided that they are within the scope of the present invention. Furthermore, the terms “comprising,” “consisting of,” “consisting of,” or “having” as used herein, unless specifically indicated to the contrary, are intended to mean that the component in question may be inherent in, and therefore should be construed to be inclusive of, rather than exclusive of, other components. All terms, including technical or scientific terms, unless otherwise defined, shall have the same meaning as commonly understood by one having ordinary knowledge in the technical field to which the invention belongs. Commonly used terms, such as dictionary-defined terms, are to be interpreted as consistent with their contextual meaning in the relevant art and are not to be construed in an idealized or unduly formal sense, unless expressly defined in the present invention.

The foregoing description is merely an exemplary description of the technical ideas of the invention, and various modifications and variations will be apparent to one having ordinary skill in the technical field to which the invention belongs without departing from the essential features of the invention. Accordingly, the embodiments disclosed herein are intended to illustrate and not to limit the technical ideas of the invention, and the scope of the technical ideas of the invention is not limited by these embodiments. The scope of protection of the present invention shall be construed in accordance with the following claims, and all technical ideas within the scope thereof shall be construed as falling within the scope of the present invention.

1-10. (canceled)

11. A converter comprising:
a housing; and
a heat dissipation passage disposed in the housing and having an inner flow channel through which a refrigerant flows,
wherein an end of the heat dissipation passage has a shape protruding from an outer surface of the housing,
wherein an anti-rotation portion is disposed at the end of the heat dissipation passage,
wherein a protrusion protruding outward beyond other areas is formed at an outer surface of the anti-rotation portion, and
wherein the outer surface of the anti-rotation portion is provided with a groove shaped to be recessed inwardly than in other areas.

12. The converter of claim 11, wherein the protrusion is plurally provided and arranged opposite each other.

13. The converter of claim 11, wherein at least a portion of the heat dissipation passage opens downward of the housing, and
wherein a cover is coupled to a lower surface of the housing and covers the heat dissipation passage.

14. The converter of claim 11, wherein the grooves are plural, and
wherein the plurality of grooves are respectively disposed on both sides of the protrusion.

15. The converter of claim 11, wherein the anti-rotation portion is formed with a smaller cross-sectional area than other regions of the heat dissipation passage.

16. The converter of claim 11, comprising a connecting tube coupled to the anti-rotation portion.

17. The converter of claim 16, wherein the connecting tube includes a guide protruding outwardly, and the anti-rotation portion is disposed on an inner side of the guide.

18. The converter of claim 11, wherein the anti-rotation portion and the heat dissipation passage are integrally formed.

19. The converter of claim 14, wherein a sum of a circumferential lengths of each of the plurality of grooves is greater than a circumferential length of the protrusion.

20. The converter of claim 11, wherein the heat dissipation passage is integrally formed with the housing.

21. The converter of claim 11, wherein the heat dissipation passage includes a first heat dissipation passage formed on a lower surface of the housing, and a second heat dissipation passage protruding from both ends of the first heat dissipation passage, and
wherein the anti-rotation portion is disposed at an end of the second heat dissipation passage.

22. The converter of claim 21, wherein the end of the second heat dissipation passage protrudes from a side of the housing.

23. The converter of claim 21, wherein a cross-sectional area of the second heat dissipation passage is smaller than a cross-sectional area of the first heat dissipation passage.

24. The converter of claim 21, wherein a cross-sectional area of the anti-rotation portion is smaller than a cross-sectional area of the second heat dissipation passage.

25. The converter of claim 21, wherein the first heat dissipation passage has a square pipe shape, and
wherein the second heat dissipation passage has a circular pipe shape.

26. A converter comprising:
a housing; and
a heat dissipation passage disposed in the housing and having an inner flow channel through which a refrigerant flows,
wherein an end of the heat dissipation passage has a shape protruding from an outer surface of the housing,
wherein an anti-rotation portion is disposed at the end of the heat dissipation passage,
wherein a protrusion protruding outward beyond other areas is formed at an outer surface of the anti-rotation portion,
wherein a plurality of grooves that are recessed inward from other areas are disposed on the outer surface of the anti-rotation portion, and
wherein a sum of a circumferential lengths of each of the plurality of grooves is greater than a circumferential length of the protrusion.

27. The converter of claim 26, wherein the heat dissipation passage includes a first heat dissipation passage formed on a lower surface of the housing, and a second heat dissipation passage protruding from both ends of the first heat dissipation passage, and
wherein the anti-rotation portion is disposed at an end of the second heat dissipation passage.

28. The converter of claim 27, wherein a cross-sectional area of the second heat dissipation passage is smaller than a cross-sectional area of the first heat dissipation passage.

29. The converter of claim 27, wherein a cross-sectional area of the anti-rotation portion is smaller than a cross-sectional area of the second heat dissipation passage.

30. The converter of claim 27, wherein the first heat dissipation passage has a square pipe shape, and
wherein the second heat dissipation passage has a circular pipe shape.
